(19) United States
(12) Patent Application Publication
(10) Pub. No.: US 2025/0141172 A1
(43) Pub. Date: May 1, 2025

(54) LASER DEVICE AND ELECTRONIC DEVICE MANUFACTURING METHOD

(71) Applicant: Gigaphoton Inc., Tochigi (JP)

(72) Inventors: Yoichi SASAKI, Oyama-shi (JP); Osamu WAKABAYASHI, Oyama-shi (JP)

(73) Assignee: Gigaphoton Inc., Tochigi (JP)

(21) Appl. No.: 18/882,513

(22) Filed: Sep. 11, 2024

(30) Foreign Application Priority Data
Oct. 27, 2023 (JP) 2023-184799

(51) Int. Cl. H01S 3/036; G03F 7/00; H01S 3/225

(52) U.S. Cl. CPC H01S 3/036; G03F 7/70025; H01S 3/2255

(57) ABSTRACT

A laser device includes a laser chamber configured to accommodate laser gas including fluorine, a pair of discharge electrodes arranged inside the laser chamber, a gas supply port arranged in the laser chamber, and an XeF₂ crystal to be vaporized as being arranged in an XeF₂ vaporization space communicating with the gas supply port.

### CROSS-REFERENCE TO RELATED APPLICATIONS

The present application claims the benefit of Japanese Patent Application No. 2023-184799, filed on Oct. 27, 2023, the entire contents of which are hereby incorporated by reference.

### BACKGROUND

### 1. Technical Field

The present disclosure relates to a laser device and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. A gas laser device with a narrowed spectral line width is referred to as a line narrowing gas laser device.

### LIST OF DOCUMENTS

### Patent Documents

Patent Document 1: US Patent Application Publication No. 2019/0237928

### SUMMARY

A laser device according to an aspect of the present disclosure includes a laser chamber configured to accommodate laser gas including fluorine, a pair of discharge electrodes arranged inside the laser chamber, a gas supply port arranged in the laser chamber, and an XeF₂ crystal to be vaporized as being arranged in an XeF₂ vaporization space communicating with the gas supply port.

An electronic device manufacturing method according to an aspect of the present disclosure includes generating laser light using a laser device, outputting the laser light to exposure apparatus, an and exposing a photosensitive substrate to the laser light in the exposure apparatus to manufacture an electronic device. Here, the laser device includes a laser chamber configured to accommodate laser gas including fluorine, a pair of discharge electrodes arranged inside the laser chamber, a gas supply port arranged in the laser chamber, and an XeF₂ crystal to be vaporized as being arranged in an XeF₂ vaporization space communicating with the gas supply port.

### BRIEF DESCRIPTION OF THE DRAWINGS

Embodiments of the present disclosure will be described below merely as examples with reference to the accompanying drawings.

FIG. 1 shows the configuration of an exposure system in a comparative example.

FIG. 2 shows the configuration of the exposure system in the comparative example.

FIG. 3 shows the configuration of a part of a laser device according to the comparative example viewed in a Z direction.

FIG. 4 shows a mechanism for supplying a xenon gas in a first embodiment.

FIG. 5 shows details of an XeF₂ container.

FIG. 6 is a table showing the relationship between a temperature T and a vapor pressure VP of an XeF₂ crystal.

FIG. 7 is a flowchart showing a procedure of supplying the xenon gas in the first embodiment.

FIG. 8 is a flowchart showing details of preprocessing in the first embodiment.

FIG. 9 is a flowchart showing details of processing of generating an XeF₂ gas in the XeF₂ container in the first embodiment.

FIG. 10 is a flowchart showing details of processing of exhausting a gas in a laser chamber in the first embodiment.

FIG. 11 is a flowchart showing details of processing of supplying a gas to the laser chamber in the first embodiment.

FIG. 12 is a flowchart showing details of processing of filling the XeF₂ container with an inert gas in the first embodiment.

FIG. 13 is a flowchart showing details of postprocessing in the first embodiment.

FIG. 14 shows an example of the relationship between XeF₂ concentration Cf and actual xenon concentration Cx.

FIG. 15 shows an example of the relationship between the XeF₂ concentration Cf and pulse energy variation.

FIG. 16 shows the configuration of a buffer tank in a second embodiment.

FIG. 17 is a flowchart showing details of processing of generating the XeF₂ gas in the XeF₂ container in the second embodiment.

FIG. 18 shows a mechanism for supplying the xenon gas in a third embodiment.

FIG. 19 shows the configuration of a part of the laser device according to a fourth embodiment viewed in a −V direction.

FIG. 20 shows the configuration of a part of the laser device according to the fourth embodiment viewed in the Z direction.

### DESCRIPTION OF EMBODIMENTS

### <Contents>

1. Comparative example
   1.1 Exposure system
   1.2 Exposure apparatus 200
      1.2.1 Configuration
      1.2.2 Operation
   1.3 Laser device 100
      1.3.1 Configuration
      1.3.2 Operation
   1.4 Problem of comparative example
2. Xenon gas supply using XeF₂ crystal
   2.1 Configuration
   2.2 Operation
      2.2.1 Main flow
      2.2.2 Preprocessing
      2.2.3 Processing of generating XeF₂ gas in XeF₂ container 47b
      2.2.4 Processing of exhausting gas in laser chamber 10
      2.2.5 Processing of supplying gas to laser chamber 10
      2.2.6 Processing of filling XeF₂ container 47b with inert gas
      2.2.7 Postprocessing
   2.3 Correction of XeF₂ concentration Cf
   2.4 Effect
3. Dissociation of XeF₂ gas by discharge reactor
   3.1 Configuration
   3.2 Operation
   3.3 Effect
4. Gas regeneration device including buffer tank 47a
   4.1 Configuration
   4.2 Operation of xenon addition in gas regeneration device 49
   4.3 Operation of xenon addition in new gas supply
   4.4 Effect
5. XeF₂ crystal 54 arranged in flow path of gas flow generated by cross flow fan 21
   5.1 Configuration
   5.2 Operation
   5.3 Effect
6. Others

Hereinafter, embodiments of the present disclosure will be described in detail with reference to the drawings. The embodiments described below shows some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

### 1.1 Exposure System

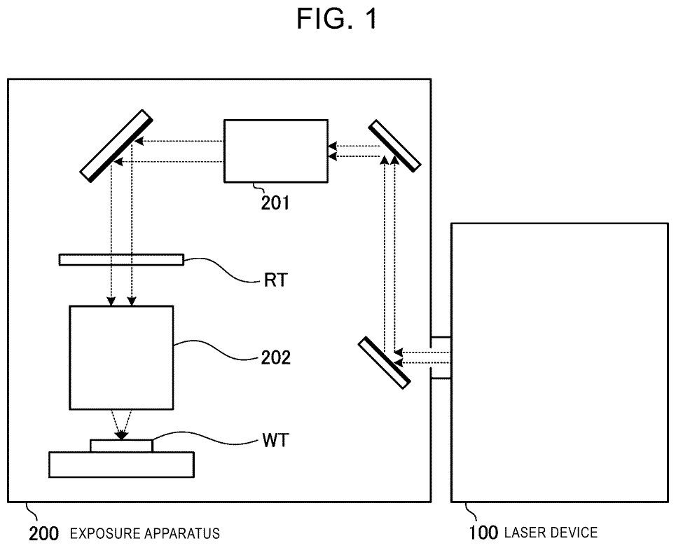

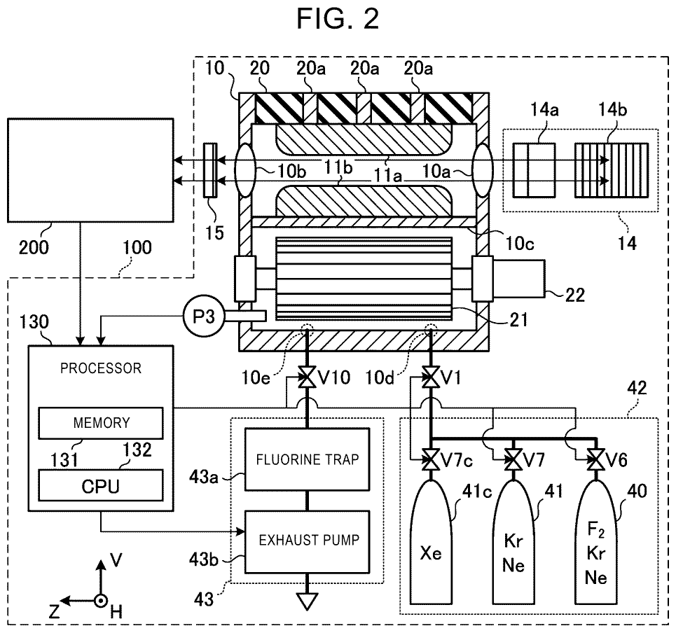

FIGS. 1 and 2 schematically show the configuration of an exposure system in a comparative example. The comparative example of the present disclosure is an example recognized by the applicant as known only by the applicant, and is not a publicly known example admitted by the applicant.

The exposure system includes a laser device 100 and an exposure apparatus 200. In FIG. 1, the laser device 100 is shown in a simplified manner. In FIG. 2, the exposure apparatus 200 is shown in a simplified manner. The laser device 100 is configured to output laser light toward the exposure apparatus 200.

### 1.2 Exposure Apparatus 200

### 1.2.1 Configuration

As shown in FIG. 1, the exposure apparatus 200 includes an illumination optical system 201 and a projection optical system 210. The illumination optical system 201 illuminates a reticle pattern of a reticle (not shown) arranged on a reticle stage RT with laser light incident from the laser device 100. The projection optical system 202 causes the laser light transmitted through the reticle to be imaged as being reduced and projected on a workpiece (not shown) arranged on a workpiece table WT. The workpiece is a photosensitive substrate such as a semiconductor wafer on which a resist film is applied.

### 1.2.2 Operation

The exposure apparatus 200 synchronously translates the reticle stage RT and the workpiece table WT in directions opposite to each other. Thus, the workpiece is exposed to the laser light reflecting the reticle pattern. Through the exposure process as described above, the reticle pattern is transferred onto the semiconductor wafer. Thereafter, an electronic device can be manufactured through a plurality of processes.

### 1.3 Laser Device 100

### 1.3.1 Configuration

As shown in FIG. 2, the laser device 100 includes a laser chamber 10, a pair of discharge electrodes 11a, 11b, a line narrowing module 14, an output coupling mirror 15, a gas supply device 42, an exhaust device 43, a processor 130, and a pressure gauge P3. The line narrowing module 14 and the output coupling mirror 15 configure an optical resonator. The laser chamber 10 is arranged on the optical path of the optical resonator. The processor 130 is a processing device including a memory 131 in which a control program is stored, and a central processing unit (CPU) 132 for executing the control program. The processor 130 is specifically configured or programmed to perform various processes included in the present disclosure.

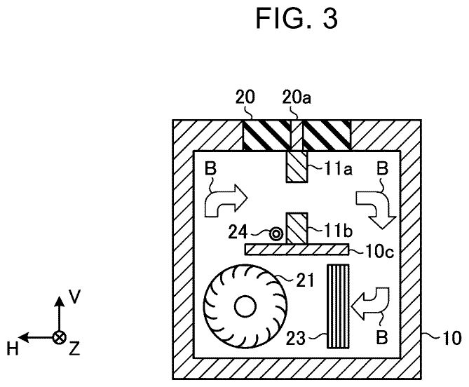

The travel direction of the laser light output from the output coupling mirror 15 is represented by a Z direction. The discharge direction between the discharge electrodes 11a, 11b is represented by a V direction or a −V direction. The Z direction and the V direction are perpendicular to other, each and the direction perpendicular to both of them is represented by a H direction or a −H direction. In FIG. 2, the configuration of the laser device 100 is shown as viewed in the −H direction. FIG. 3 shows the configuration of a part of the laser device 100 according to the comparative example viewed in the Z direction.

The laser chamber 10 accommodates the discharge electrodes 11a, 11b, a cross flow fan 21, a heat exchanger 23, and a preionization electrode 24. Windows 10a, 10b are provided at both ends of the laser chamber 10 in the Z direction. The cross flow fan 21 corresponds to the fan in the present disclosure.

The laser chamber 10 is filled with a laser gas containing, for example, an argon gas or a krypton gas as a rare gas, a fluorine gas as a halogen gas, a neon gas as a buffer gas, and the like. Alternatively, a laser gas containing a fluorine gas and a buffer gas may be enclosed.

An opening is formed in a part of the laser chamber 10, which is closed by an electrically insulating portion 20. The electrically insulating portion 20 supports the discharge electrode 11a. A plurality of conductive portions 20a are embedded in the electrically insulating portion 20. Each of the conductive portions 20a is electrically connected to the discharge electrode 11a. A power source device (not shown) is connected to the discharge electrode 11a via the conductive portions 20a.

A return plate 10c is arranged in the laser chamber 10. The discharge electrode 11b is supported by the return plate 10c. The discharge electrode 11b is electrically connected to the ground potential via the return plate 10c and a conductive member of the laser chamber 10. As shown in FIG. 3, the return plate 10c defines a gap through which the laser gas passes on each of the front and back sides of the paper surface of FIG. 2. A rotary shaft of the cross flow fan 21 is supported by a bearing fixed to the laser chamber 10 and is connected to a motor 22 arranged outside the laser chamber 10.

The preionization electrode 24 includes a dielectric pipe, a preionization inner electrode arranged inside the dielectric pipe, and one or more preionization outer electrodes arranged on the surface of the dielectric pipe. The preionization electrode 24 is arranged along the longitudinal direction of the discharge electrode 11b at a position upstream the position of the discharge electrode 11b in the circulation direction of the laser gas.

The line narrowing module 14 includes a prism 14a and a grating 14b. The prism 14a and the grating 14b are arranged in this order on the optical path of the light output from the window 10a.

The gas supply device 42 includes a fluorine-containing gas cylinder 40, an inert gas cylinder 41, and a xenon gas cylinder 41c. In the present disclosure, a KrF excimer laser device is exemplified. In this case, the fluorine-containing gas cylinder 40 accommodates a fluorine-containing gas composed of a neon gas, 1.25% krypton gas, and 1% fluorine gas, and the inert gas cylinder 41 accommodates an inert gas composed of a neon gas and 1.25% krypton gas. The total chamber pressure and the fluorine concentration can be adjusted by adjusting the total amount and the partial pressure ratio of gases supplied from the fluorine-containing gas cylinder 40 and the inert gas cylinder 41 to the laser chamber 10. For example, when a target pressure P(F₂) after fluorine-containing gas injection to the laser chamber 10 in a substantially vacuum condition is 30 kPa, and a target total pressure Pt after inert gas injection is 300 kPa, the fluorine concentration in the laser chamber 10 becomes 0.1%.

In order to stabilize a pulse energy E of the laser light, a small amount of a xenon gas may be injected into the laser chamber 10 from the xenon gas cylinder 41c. The optimum concentration of the xenon gas is about 10 ppm.

Pipes connected to the fluorine-containing gas cylinder 40, the inert gas cylinder 41, and the xenon gas cylinder 41c are provided with valves V6, V7, V7c, respectively. These pipes join together into one pipe provided with a valve V1 and are connected to a gas supply port 10d of the laser chamber 10. The valve V1 corresponds to the first valve in the present disclosure, and the pipe provided with the valve V1 corresponds to the first pipe in the present disclosure.

The exhaust device 43 includes a fluorine trap 43a and an exhaust pump 43b. A valve V10 is provided in a pipe connected to the exhaust device 43, and the pipe is connected to a gas discharge port 10e of the laser chamber 10. The fluorine trap 43a removes at least fluorine from the laser gas discharged from the laser chamber 10. The exhaust pump 43b is configured to exhaust the gas having passed through the fluorine trap 43a to the outside of the laser device 100 so that the inside of the laser chamber 10 can be brought into a substantially vacuum state. The substantially vacuum state is a state of, for example, 0.1 kPa or less.

The pressure gauge P3 is configured to measure the pressure in the laser chamber 10.

### 1.3.2 Operation

The processor 130 receives setting data of a target value Et of the pulse energy E and a light emission trigger signal from the exposure apparatus 200. The processor 130 transmits the setting data of the charge voltage to a charger included in the power source device based on the setting data of the target value Et of the pulse energy E. Further, the processor 130 transmits a trigger signal to the power source device based on the light emission trigger signal. Upon receiving the trigger signal from the processor 130, the power source device generates a pulse high voltage from the electric energy charged to the charger and applies the high voltage between the discharge electrodes 11a, 11b.

When the high voltage is applied between the discharge electrodes 11a, 11b, discharge occurs between the discharge electrodes 11a, 11b. This discharge is referred to as main discharge. The laser medium in the laser chamber 10 is excited by the energy of the discharge and shifts to a high energy level. When the excited laser medium then shifts to a low energy level, light having a wavelength corresponding to the difference between the energy levels is emitted.

The light generated in the laser chamber 10 is output to the outside of the laser chamber 10 through the windows 10a, 10b. The beam width in the H direction of the light output through the window 10a of the laser chamber 10 is expanded by the prism 14a, and then the light is incident on the grating 14b.

The light incident on the grating 14b is reflected by a plurality of grooves of the grating 14b and is diffracted in a direction corresponding to the wavelength of the light. By matching the incident angle of the light incident on the grating 14b with the diffraction angle of the diffracted light having a desired wavelength, the wavelength of the diffracted light incident on the prism 14a from the grating 14b is selected. The prism 14a reduces the beam width in the H direction of the diffracted light incident thereon from the grating 14b and returns the light to the laser chamber 10 through the window 10a.

The output coupling mirror 15 transmits and outputs a part of the light output from the window 10b of the laser chamber 10, and reflects the other part back into the laser chamber 10.

In this way, the light output from the laser chamber 10 reciprocates between the line narrowing module 14 and the output coupling mirror 15, and is amplified each time the light passes through the discharge space between the discharge electrodes 11a, 11b. The light is line narrowed each time being turned back in the line narrowing module 14. Thus, the light having undergone laser oscillation and line narrowing is output as laser light from the output coupling mirror 15.

When the motor 22 rotates the cross flow fan 21, the laser gas flows and circulates through the inside of the laser chamber 10 as indicated by arrow B in FIG. 3. Discharge products generated by the discharge between the discharge electrodes 11a, 11b are removed from the discharge space by the flow of the laser gas by the time of the subsequent discharge, and the discharge space and the vicinity thereof are in a state in which there is little discharge products, so that the discharge can be stabilized. The heat exchanger 23 exhausts the thermal energy of the laser gas, which has reached a high temperature due to the discharge, to the outside of the laser chamber 10.

Immediately before the main discharge, a voltage is applied between the preionization outer electrode and the preionization inner electrode included in the preionization electrode 24, and corona discharge occurs around the preionization electrode 24. Light having a short wavelength is generated by the corona discharge. The light having a short wavelength ionizes xenon between the discharge electrodes 11a, 11b. Ionizing xenon before the main discharge is referred to as preionization. By the preionization, it is possible to cause the main discharge with less deviation in the longitudinal direction of the discharge electrodes 11a, 11b, and thus stable laser light can be output.

As discharge between the discharge electrodes 11a, 11b is repeated in the laser chamber 10, impurities contained in the laser gas increase or the fluorine concentration decreases, so that the laser gas is to be replaced or replenished. For example, the procedure for replacing all the gases in the laser chamber 10 is as follows.
(1) The gas in the laser chamber 10 is exhausted by the exhaust device 43, and the inside of the laser chamber 10 is brought into a substantially vacuum state.
(2) The fluorine-containing gas is injected into the laser chamber 10 from the fluorine-containing gas cylinder 40 by the gas supply device 42.
(3) A small amount of the xenon gas is injected into the laser chamber 10 from the xenon gas cylinder 41c by the gas supply device 42.
(4) The inert gas is injected into the laser chamber 10 from the inert gas cylinder 41 by the gas supply device 42.

### 1.4 Problem of Comparative Example

Although the injection of a small amount of the xenon gas has an effect such as stabilization of the pulse energy E, there are three problems as follows, and the use of the xenon gas may be abandoned due to the high cost for solving these problems.
(1) In addition to the fluorine-containing gas cylinder 40 and the inert gas cylinder 41, it is necessary to add equipment and pipes for installing the xenon gas cylinder 41c.
(2) Generally, a gas cylinder is filled with a gas of 10 MPa or more, and when such a gas cylinder is transported from a manufacturing site, special transportation method and permission of a government authority are required.
(3) Assuming that the total pressure in the laser chamber 10 is 300 kPa, the partial pressure of the xenon gas of 10 ppm is 0.003 kPa, and it is difficult to accurately measure such a small pressure and to introduce it into the laser chamber 10.

### 2. Xenon Gas Supply Using XeF₂ Crystal

### 2.1 Configuration

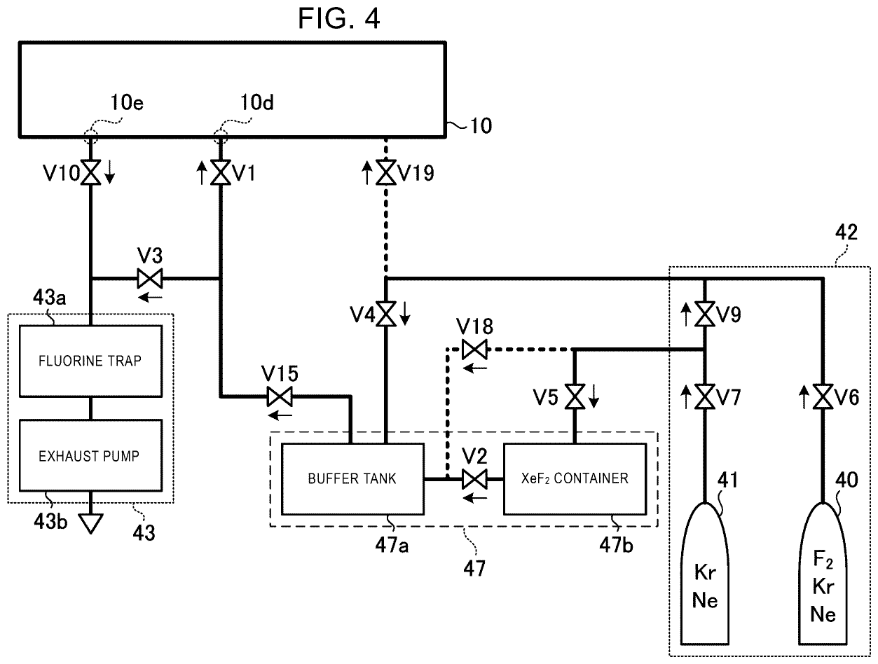

FIG. 4 shows a mechanism for supplying the xenon gas in the first embodiment. To supply the xenon gas to the laser chamber 10, a buffer tank 47a and an XeF₂ container 47b are connected to the gas supply port 10d via pipes. In FIG. 4, each valve is indicated with an arrow to indicate a typical flow direction of a gas in the pipe, but each valve need not be a check valve.

The buffer tank 47a is a sealable container that communicates with the laser chamber 10 via a pipe including a valve V1 and a pipe including a valve V15. The XeF₂ container 47b is a sealable container that communicates with the buffer tank 47a via a pipe including a valve V2. The valve V2 corresponds to the second valve in the present disclosure, and the pipe including the valve V2 corresponds to the second pipe in the present disclosure.

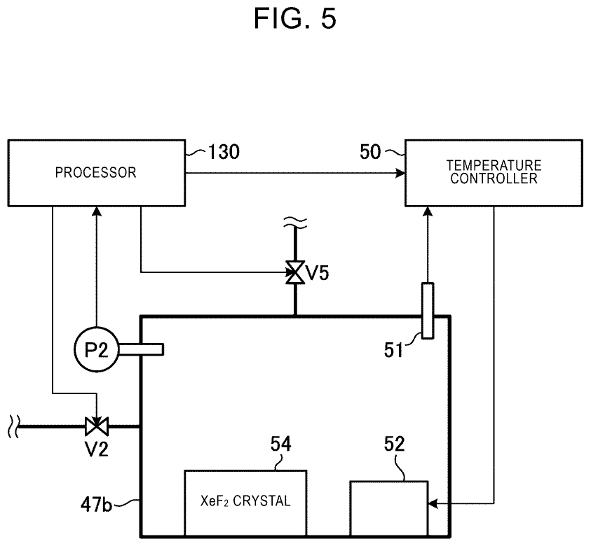

FIG. 5 shows details of the XeF₂ container 47b. The XeF₂ container 47b accommodates an XeF₂ crystal 54 therein. The XeF₂ crystal 54 is a sublimable solid and has a vapor pressure VP of about 0.5 kPa at 25° C.

In the XeF₂ container 47b, a temperature sensor 51, a temperature adjuster 52, and a pressure gauge P2 are arranged. The temperature sensor 51 measures a temperature in the XeF₂ container 47b, preferably a temperature T of the XeF₂ crystal 54, and outputs the measurement result to a temperature controller 50. The temperature adjuster 52 includes a heater, a chiller, or the both, and adjusts the temperature T of the XeF₂ crystal 54 by adjusting the temperature in the XeF₂ container 47b. The temperature controller 50 controls, in accordance with a control signal received from the processor 130, the temperature adjuster 52 based on the measurement result of the temperature sensor 51. Accordingly, the vapor pressure VP of the XeF₂ crystal 54 is adjusted. The pressure gauge P2 measures the gas pressure in the XeF₂ container 47b and outputs the measurement result to the processor 130.

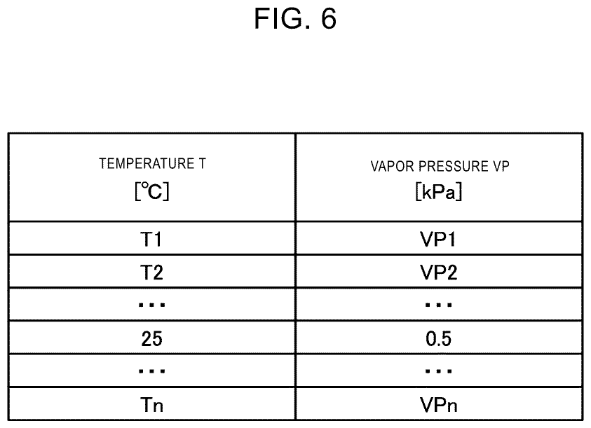

FIG. 6 is a table showing the relationship between the temperature T and the vapor pressure VP of the XeF₂ crystal 54. The data of the vapor pressure VP of the XeF₂ crystal 54 at each temperature T is stored in advance in the memory 131 (see FIG. 2) in the temperature range in which the temperature can be adjusted by the temperature adjuster 52, the minimum value and the maximum value thereof being T1 and Tn, respectively. The processor 130 can refer to this data to calculate a target value of the temperature T for obtaining a desired vapor pressure VP.

Referring back to FIG. 4, the buffer tank 47a and the XeF₂ container 47b configure an XeF₂ vaporization space 47. The XeF₂ vaporization space 47 communicates with the laser chamber 10 via the pipe including the valve V1 and the pipe including the valve V15.

The buffer tank 47a is connected to the exhaust device 43 via a pipe including a valve V3 and the pipe including the valve V15. The valve V3 corresponds to the third valve in the present disclosure. The exhaust device 43 can exhaust the XeF₂ vaporization space 47 to a substantially vacuum state. The XeF₂ vaporization space 47 is brought into a substantially vacuum state, the valves V3, V15 are closed, and by waiting for a while, the inside of the XeF₂ vaporization space 47 is filled with the XeF₂ gas having a pressure corresponding to the vapor pressure VP of the XeF₂ crystal 54.

The XeF₂ vaporization space 47 communicates with the gas supply device 42 via a pipe including a valve V4. The valve V4 corresponds to the fourth valve in the present disclosure. When the valves V4, V15, V1 are opened, the laser chamber 10 and the gas supply device 42 communicate with each other via the XeF₂ vaporization space 47. The valve V6 is opened to supply the fluorine-containing gas to the laser chamber 10, and the valves V7, V9 are opened to supply the inert gas. Accordingly, the XeF₂ gas in the XeF₂ vaporization space 47 is introduced into the laser chamber 10 together with the gas supplied from the fluorine-containing gas cylinder 40 or the inert gas cylinder 41. The XeF₂ gas introduced into the laser chamber 10 is easily dissociated due to the discharge between the discharge electrodes 11a, 11b.

The pipe including the valve V4 is connected to the buffer tank 47a in the XeF₂ vaporization space 47. Further, when the valve V2 is closed, communication between the buffer tank 47a and the XeF₂ container 47b is blocked. Therefore, when the valve V2 is closed and the valves V4, V15, V1 are opened, the XeF₂ gas to be introduced into the laser chamber 10 can be limited to only the XeF₂ gas in the buffer tank 47a.

A pipe including a valve V19 may be used for supplying the gas to the laser chamber 10 directly from the fluorine-containing gas cylinder 40 or the inert gas cylinder 41 without introducing the XeF₂ gas into the laser chamber 10. The pipe including the valve V19 may be connected to the pipe including the valve V1 instead of being directly connected to the laser chamber 10.

The XeF₂ container 47b communicates with the gas supply device 42 via a pipe including a valve V5. The valve V5 corresponds to the fifth valve in the present disclosure. In a period in which the XeF₂ gas is not generated or supplied to the laser chamber 10, vaporization of the XeF₂ crystal 54 can be suppressed by filling the XeF₂ container 47b with a gas. The XeF₂ container 47b is preferably filled with the inert gas in the inert gas cylinder 41 via a pipe including the valve V7 and the pipe including the valve V5. The valve V2 may be opened to fill the entire XeF₂ vaporization space 47 with the inert gas as well as the XeF₂ container 47b. Further, instead of the valve V5, the XeF₂ vaporization space 47 may be filled with the inert gas via a valve V18.

Although FIG. 4 shows a case in which one gas supply device 42, one exhaust device 43, and one XeF₂ vaporization space 47 are connected to one laser chamber 10, the present disclosure is not limited thereto. One gas supply device 42, one exhaust device 43, and one XeF₂ vaporization space 47 may be connected to a plurality of the laser chambers 10.

In other respects, the configuration of the first embodiment is similar to that of the comparative example.

### 2.2 Operation

### 2.2.1 Main Flow

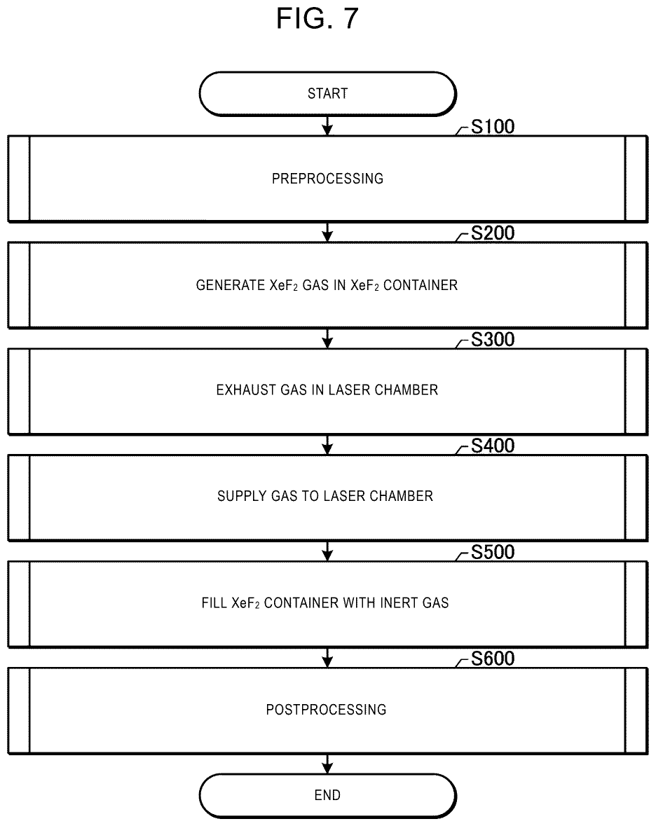

FIG. 7 is a flowchart showing a procedure of supplying the xenon gas in the first embodiment.

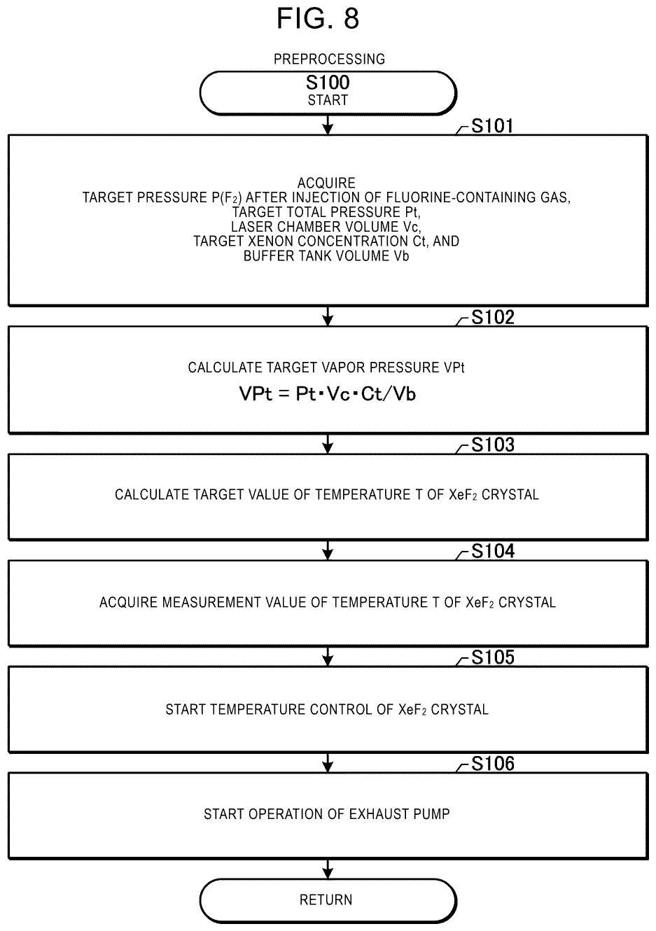

In S100, the processor 130 performs preprocessing for supplying the laser gas together with the XeF₂ gas to the laser chamber 10. Details of S100 will be described later with reference to FIG. 8.

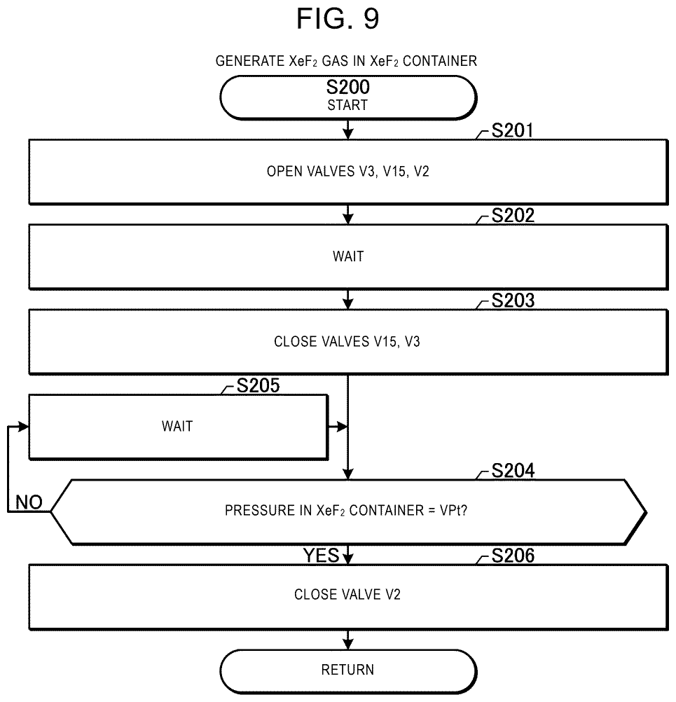

In S200, the processor 130 controls the various valves so that the XeF₂ gas is generated in the XeF₂ container 47b. Details of S200 will be described later with reference to FIG. 9.

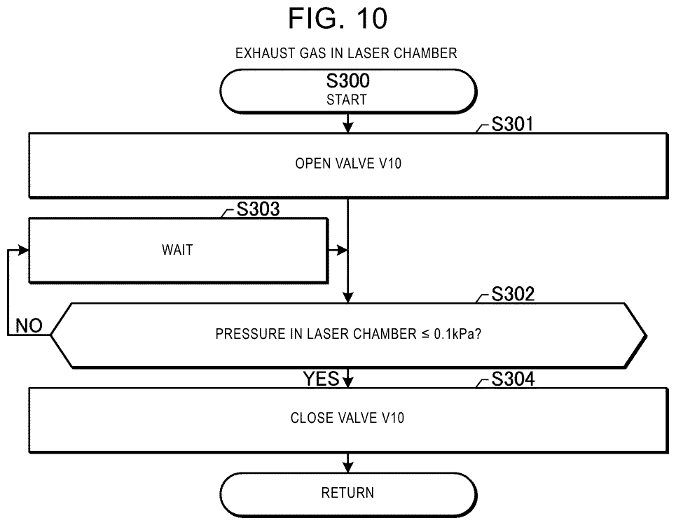

In S300, the processor 130 controls the various valves so that the gas in the laser chamber 10 is exhausted. Details of S300 will be described later with reference to FIG. 10.

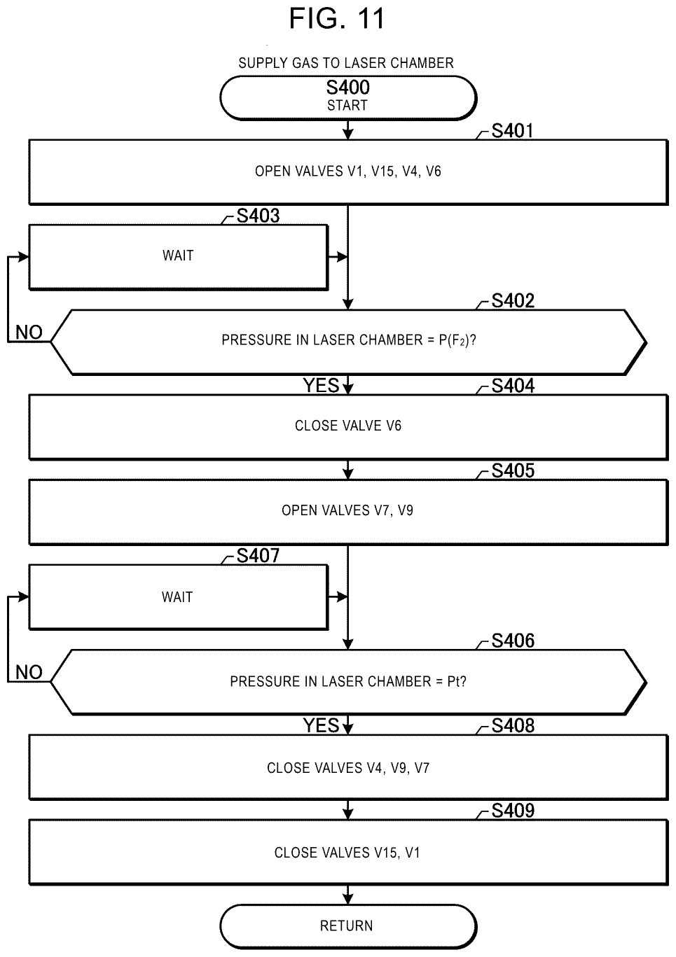

In S400, the processor 130 controls the various valves so that the laser gas is supplied together with the XeF₂ gas into the laser chamber 10. Details of S400 will be described later with reference to FIG. 11.

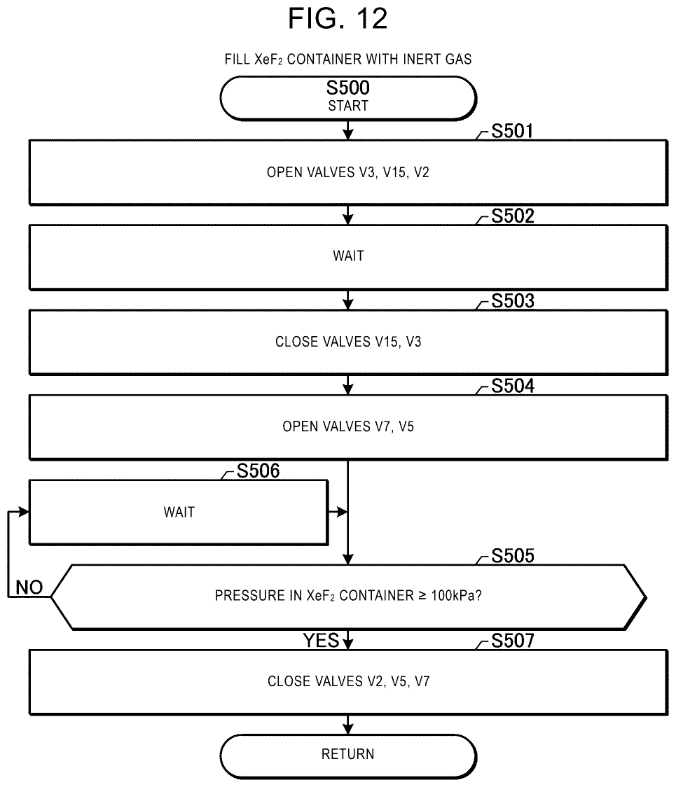

In S500, the processor 130 controls the various valves to fill the XeF₂ container 47b with the inert gas. Details of S500 will be described later with reference to FIG. 12.

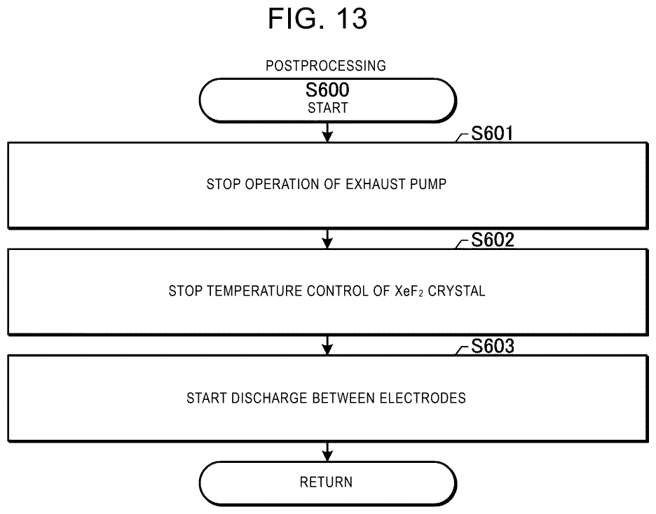

In S600, the processor 130 performs postprocessing, which is processing after laser gas is supplied to the laser chamber 10. Details of S600 will be described later with reference to FIG. 13.

After S600, the processor 130 ends processing of the flowchart.

### 2.2.2 Preprocessing

FIG. 8 is a flowchart showing details of the preprocessing in the first embodiment. The processes shown in FIG. 8 correspond to the subroutine of S100 of FIG. 7.

In S101, the processor 130 acquires the following data.
Target pressure P(F₂) after injection of fluorine-containing gas
Target total pressure Pt
Laser chamber volume Vc
Target xenon concentration Ct
Buffer tank volume Vb

The target total pressure Pt and the target xenon concentration Ct are determined in accordance with the required laser performance. The target pressure P(F₂) after injection of the fluorine-containing gas is determined from the target fluorine concentration in the laser chamber 10 and the target total pressure Pt. The laser chamber volume Vc and the buffer tank volume Vb may be stored in the memory 131 in advance.

In S102, the processor 130 calculates a target vapor pressure VPt of the XeF₂ crystal 54. If the XeF₂ gas inside the buffer tank 47a is entirely introduced into the laser chamber 10, an XeF₂ concentration Cf in the laser chamber 10 is given by the following expression 1.

$$C f = ( VPt \cdot Vb ) / ( Pt \cdot Vc ) \qquad Expression 1$$

From expression 1, the target vapor pressure VPt may be set to the following value.

$$V P t = Pt \cdot Vc \cdot Cf / Vb \qquad Expression 2$$

Here, when the XeF₂ gas introduced into the laser chamber 10 is entirely dissociated into a xenon gas and a fluorine gas, the XeF₂ concentration Cf is supposed to coincide with the target xenon concentration Ct, and thus the target vapor pressure VPt is given by the following expression.

$$V P t = Pt \cdot Vc \cdot Ct / Vb$$

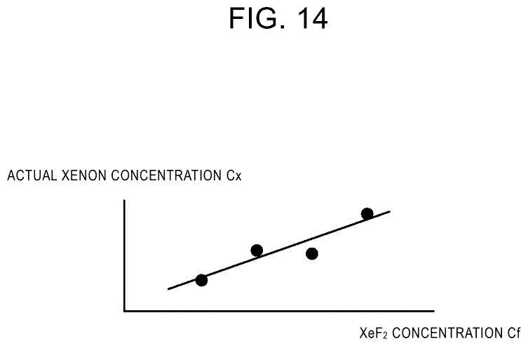

Correction in a case in which the XeF₂ concentration Cf calculated by expression 1 does not coincide with an actual xenon concentration Cx will be described later with reference to FIG. 14.

In S103, the processor 130 calculates the target value of the temperature T of the XeF₂ crystal 54. The target value of the temperature T of the XeF₂ crystal 54 can be calculated based on the target vapor pressure VPt and the data shown in FIG. 6.

In S104, the processor 130 acquires a measurement value of the temperature T of the XeF₂ crystal 54 from the temperature sensor 51 (see FIG. 5).

In S105, the processor 130 starts temperature control of the XeF₂ crystal 54 by the temperature adjuster 52. The temperature control is performed via the temperature controller 50 and continued until being stopped in S602 of FIG. 13.

In S106, the processor 130 starts operation of the exhaust pump 43b. At this time, operation of exhausting the laser chamber 10 and the buffer tank 47a is not performed. The operation of exhausting these spaces is turned on and off by opening and closing the valves. The operation of the exhaust pump 43b is continued until being stopped in S601 of FIG. 13.

After S106, the processor 130 terminates processing of the present flowchart and returns to processing shown in FIG. 7.

2.2.3 Processing of Generating XeF₂ Gas in XeF₂ Container 47b

FIG. 9 is a flowchart showing details of processing of generating the XeF₂ gas in the XeF₂ container 47b in the first embodiment. The processes shown in FIG. 9 correspond to the subroutine of S200 of FIG. 7.

In S201, the processor 130 opens the valves V3, V15, V2. Accordingly, the inside of the buffer tank 47a and the XeF₂ container 47b is exhausted.

In S202, the processor 130 waits for a certain period of time. The pressure in the buffer tank 47a and the XeF₂ container 47b after waiting for the certain period of time corresponds to the first pressure in the present disclosure. Although it is preferable that the first pressure corresponds to a substantially vacuum state, the first pressure is not limited thereto and is only required to be a pressure lower than the target vapor pressure VPt.

In S203, the processor 130 closes the valves V15, V3. Accordingly, communication between the XeF₂ vaporization space 47 and the exhaust device 43 is blocked. Further, generation of the XeF₂ gas is started in the XeF₂ vaporization space 47. The temperature T of the XeF₂ crystal 54 is controlled to a temperature corresponding to the target vapor pressure VPt. The target vapor pressure VPt corresponds to the second pressure in the present disclosure.

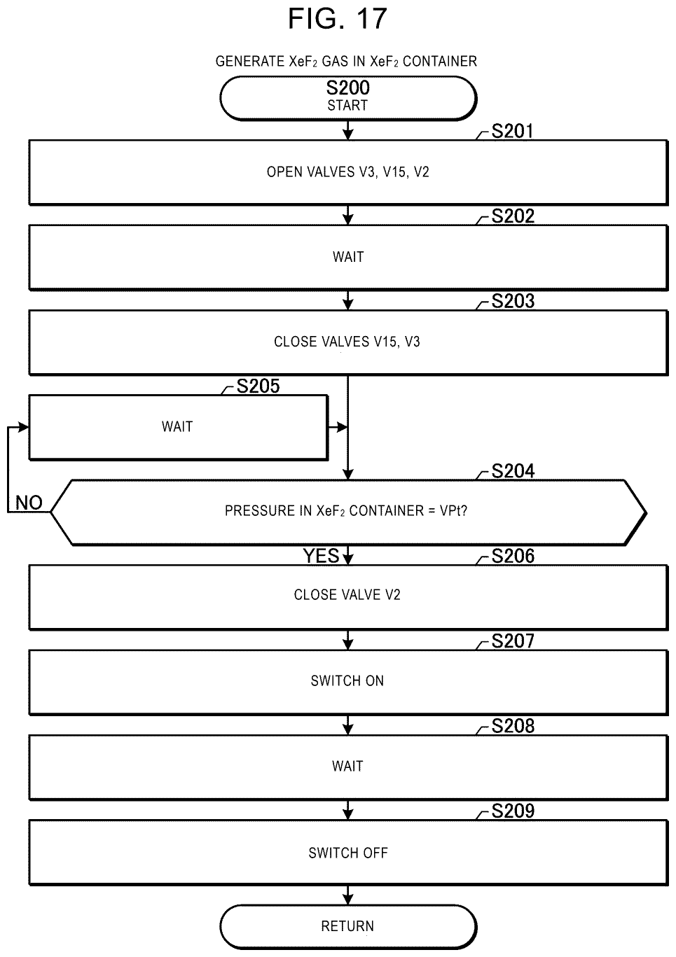

In S204, the processor 130 determines whether or not the gas pressure acquired from the pressure gauge P2 of the XeF₂ container 47b has reached the target vapor pressure VPt. Although an equal sign is shown in FIG. 9, it is not necessary to be completely identical, and it is sufficient to determine whether or not the difference is within a predetermined error range. The same applies to FIGS. 11 and 17.

When the gas pressure in the XeF₂ container 47b has not reached the target vapor pressure VPt (S204: NO), the processor 130 advances processing to S205. In S205, the processor 130 waits for a certain period of time, and then returns processing to S204.

When the gas pressure in the XeF₂ container 47b has reached the target vapor pressure VPt (S204: YES), the processor 130 advances processing to S206. In S206, the processor 130 closes the valve V2. Accordingly, communication between the buffer tank 47a and the XeF₂ container 47b is blocked.

After S206, the processor 130 terminates processing of the present flowchart and returns to processing shown in FIG. 7.

### 2.2.4 Processing of Exhausting Gas in Laser Chamber 10

FIG. 10 is a flowchart showing details of processing of exhausting the gas in the laser chamber 10 in the first embodiment. The processes shown in FIG. 10 correspond to the subroutine of S300 of FIG. 7.

In S301, the processor 130 opens the valve V10. Accordingly, exhaust of the inside of the laser chamber 10 is started.

In S302, the processor 130 determines whether or not the pressure in the laser chamber 10 acquired from the pressure gauge P3 is equal to or less than 0.1 kPa.

When the pressure in the laser chamber 10 is more than 0.1 kPa (S302: NO), the processor 130 advances processing to S303. In S303, the processor 130 waits for a certain period of time, and then returns processing to S302.

When the pressure in the laser chamber 10 is equal to or less than 0.1 kPa (S302: YES), the processor 130 advances processing to S304. In S304, the processor 130 closes the valve V10. Accordingly, communication between the laser chamber 10 and the exhaust device 43 is blocked.

After S304, the processor 130 terminates processing of the present flowchart and returns to processing shown in FIG. 7.

### 2.2.5 Processing of Supplying Gas to Laser Chamber 10

FIG. 11 is a flowchart showing details of processing of supplying a gas to the laser chamber 10 in the first embodiment. The processes shown in FIG. 11 correspond to the subroutine of S400 of FIG. 7.

In S401, the processor 130 opens the valves V1, V15, V4, V6. Accordingly, the fluorine-containing gas in the fluorine-containing gas cylinder 40 is supplied to the laser chamber 10 together with the XeF₂ gas in the buffer tank 47a.

In S402, the processor 130 determines whether or not the pressure in the laser chamber 10 acquired from the pressure gauge P3 has reached the target pressure P(F₂) after injection of the fluorine-containing gas.

When the pressure in the laser chamber 10 has not reached the target pressure P(F₂) (S402: NO), the processor 130 advances processing to S403. In S403, the processor 130 waits for a certain period of time, and then returns processing to S402.

When the pressure in the laser chamber 10 has reached the target pressure P(F₂) (S402: YES), the processor 130 advances processing to S404. In S404, the processor 130 closes the valve V6. Accordingly, supply of the fluorine-containing gas from the gas supply device 42 to the buffer tank 47a is stopped.

In S405, the processor 130 opens the valves V7, V9. Accordingly, the inert gas in the inert gas cylinder 41 is supplied to the laser chamber 10 via the buffer tank 47a. When the XeF₂ gas remains in the buffer tank 47a, the inert gas is supplied to the laser chamber 10 together with the XeF₂ gas.

In S406, the processor 130 determines whether or not the pressure in the laser chamber 10 acquired from the pressure gauge P3 has reached the target total pressure Pt in the laser chamber 10.

When the pressure in the laser chamber 10 has not reached the target total pressure Pt (S406: NO), the processor 130 advances processing to S407. In S407, the processor 130 waits for a certain period of time, and then returns processing to S406.

When the pressure in the laser chamber 10 has reached the target total pressure Pt (S406: YES), the processor 130 advances processing to S408. In S408, the processor 130 closes the valves V4, V9, V7. Accordingly, supply of the inert gas from the gas supply device 42 to the buffer tank 47a is stopped.

In S409, the processor 130 closes the valves V15, V1. Accordingly, communication between the laser chamber 10 and the buffer tank 47a is blocked.

After S409, the processor 130 terminates processing of the present flowchart and returns to processing shown in FIG. 7.

2.2.6 Processing of Filling XeF₂ Container 47b with Inert Gas

FIG. 12 is a flowchart showing details of processing of filling the XeF₂ container 47b with the inert gas in the first embodiment. The processes shown in FIG. 12 correspond to the subroutine of S500 of FIG. 7.

Processes of S501 to S503 are similar to those of S201 to S203 of FIG. 9. Accordingly, the inside of the buffer tank 47a and the XeF₂ container 47b is exhausted.

In S504, the processor 130 opens the valves V7, V5. Accordingly, the inert gas in the inert gas cylinder 41 is supplied to the XeF₂ container 47b and the buffer tank 47a.

In S505, the processor 130 determines whether or not the gas pressure acquired from the pressure gauge P2 of the XeF₂ container 47b is equal to or more than 100 kPa.

When the gas pressure in the XeF₂ container 47b is less than 100 kPa value (S505: NO), the processor 130 advances processing to S506. In S506, the processor 130 waits for a certain period of time, and then returns processing to S505.

When the gas pressure in the XeF₂ container 47b is equal to or more than 100 kPa (S505: YES), the processor 130 advances processing to S507. In S507, the processor 130 closes the valves V2, V5, V7. Accordingly, filling of the inert gas from the gas supply device 42 to the XeF₂ vaporization space 47 is completed.

After S507, the processor 130 terminates processing of the present flowchart and returns to processing shown in FIG. 7.

### 2.2.7 Postprocessing

FIG. 13 is a flowchart showing details of the postprocessing in the first embodiment. The processes shown in FIG. 13 correspond to the subroutine of S600 of FIG. 7.

In S601, the processor 130 stops operation of the exhaust pump 43b. In S602, the processor 130 stops the temperature control of the XeF₂ crystal 54. In S603, the processor 130 starts discharge between the discharge electrodes 11a, 11b. Accordingly, the XeF₂ gas is dissociated into a xenon gas and a fluorine gas. Discharge between the discharge electrodes 11a, 11b may be performed for outputting laser light to the exposure apparatus 200, or may be performed with a shutter (not shown) between the laser device 100 and the exposure apparatus 200 closed.

After S603, the processor 130 terminates processing of the present flowchart and returns to processing shown in FIG. 7.

### 2.3 Correction of XeF₂ Concentration Cf

The above description is based on the assumption that the XeF₂ concentration Cf calculated by expression coincides with the actual xenon concentration Cx, but there may be a case in which they do not match. For example, there may be a case in which a part of the XeF₂ gas introduced into the laser chamber 10 is not dissociated or a case in which the XeF₂ gas recombines after being once dissociated.

FIG. 14 shows an example of the relationship between the XeF₂ concentration Cf and the actual xenon concentration Cx. The XeF₂ concentration Cf be may corrected based on such a relationship. For example, it is assumed that the XeF₂ concentration Cf calculated by expression 1 and the actual xenon concentration Cx can be approximated by the following a expression using proportional constant A.

Cx=A·Cf

In this case, from expression 2, the target vapor pressure VPt is given by the following expression.

$$V P t = Pt \cdot Vc \cdot ( Ct / A ) / Vb$$

As a method for measuring the xenon concentration Cx to obtain the relationship shown in FIG. 14, there are a method of analyzing a sample gas by a mass spectrometer, and a method of analyzing the emission intensity light having a wavelength of 354 nm, which is correlated with the xenon concentration Cx, by spectrally dispersing inter-electrode discharge light by a spectrometer. The wavelength of 354 nm corresponds to the wavelength of an emission line of XeF. Such measurement may be performed before transportation of the laser device 100, and the relationship shown in FIG. 14 may be stored in the memory 131. Further, a mass spectrometer or a spectrometer may be attached to the laser device 100, and the xenon concentration Cx may be measured at any time.

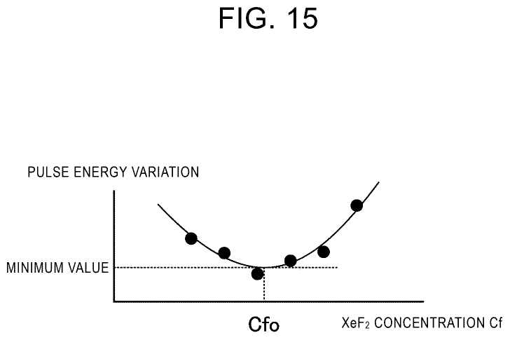

FIG. 15 shows an example of the relationship between the XeF₂ concentration Cf and pulse energy variation. The pulse energy variation is obtained, for example, by dividing the standard deviation of the pulse energy E of the laser light by the average value thereof. The smaller the pulse energy variation is, the better the stability of the pulse energy E is. The pulse energy E can be measured by arranging an energy sensor (not shown) on the optical path of the laser light. An optimum value Cfo of the XeF₂ concentration Cf may be determined based on the relationship as shown in FIG. 15. In this case, from expression 2, the target vapor pressure VPt is given by the following expression.

$$V P t = Pt \cdot Vc \cdot Cfo / Vb$$

### 2.4 Effect

In the first embodiment, the laser device 100 includes the laser chamber 10 accommodating the laser gas containing fluorine, the pair of discharge electrodes 11a, 11b arranged in the laser chamber 10, the gas supply port 10d arranged in the laser chamber 10, and the XeF₂ crystal 54 to be vaporized as being arranged in the XeF₂ vaporization space 47 communicating with the gas supply port 10d.

Accordingly, the XeF₂ gas generated from the XeF₂ crystal 54 is introduced into the laser chamber 10, and the XeF₂ gas is dissociated into a xenon gas and a fluorine gas due to the discharge, so that the pulse energy E of the laser light can be stabilized even without using the xenon gas cylinder 41c.

According to the first embodiment, the laser device 100 further includes the temperature adjuster 52 for adjusting the temperature T of the XeF₂ crystal 54.

Accordingly, since the supply rate of the XeF₂ gas can be adjusted by adjusting the temperature T of the XeF₂ crystal 54, the xenon concentration Cx in the laser chamber 10 can be adjusted to an optimum range.

According to the first embodiment, the laser device 100 further includes the processor 130 for controlling the temperature adjuster 52 based on the target total pressure Pt and the target xenon concentration Ct of the laser gas in the laser chamber 10.

Accordingly, the xenon concentration Cx can be accurately adjusted by controlling the temperature adjuster 52 in accordance with operating conditions of the laser device 100.

According to the first embodiment, the processor 130 determines the target vapor pressure VPt of the XeF₂ crystal 54 based on the target total pressure Pt and the target xenon concentration Ct, and controls the temperature adjuster 52 based on the target vapor pressure VPt.

Accordingly, by determining the target vapor pressure VPt, the generation rate of the XeF₂ gas can be adjusted with high accuracy.

According to the first embodiment, the XeF₂ vaporization space 47 communicates with the laser chamber 10 via the first pipe including the valve V1.

Accordingly, since the generation amount of the XeF₂ gas can be limited by blocking communication between the XeF₂ vaporization space 47 and the laser chamber 10 by the valve V1 during the period in which the XeF₂ crystal 54 is vaporized, the xenon concentration Cx in the laser chamber 10 can be brought close to the optimum range.

According to the first embodiment, the XeF₂ vaporization space 47 includes the buffer tank 47a communicating with the laser chamber 10 via the first pipe including the valve V1, and the XeF₂ container 47b communicating with the buffer tank 47a via the second pipe including the valve V2 and accommodating the XeF₂ crystal 54.

Accordingly, with the XeF₂ vaporization space 47 divided into the XeF₂ container 47b and the buffer tank 47a, the supply amount of the XeF₂ gas can be adjusted with high accuracy by supplying the XeF₂ gas in the buffer tank 47a to the laser chamber 10.

According to the first embodiment, the laser device includes the exhaust device 43 for exhausting the inside of the XeF₂ vaporization space 47, the valve V3 arranged between the XeF₂ vaporization space 47 and the exhaust device 43, and the processor 130. The processor 130 opens the valve V3, controls the exhaust device 43 so that the pressure in the XeF₂ vaporization space 47 becomes the first pressure, closes the valve V3, and controls the temperature adjuster 52 such that the vapor pressure VP of the XeF₂ crystal 54 becomes the target vapor pressure VPt higher than the first pressure.

Accordingly, by exhausting the inside of the XeF₂ vaporization space 47, the amount of the XeF₂ gas generated in the XeF₂ vaporization space 47 can be accurately control.

According to the first embodiment, the XeF₂ vaporization space 47 communicates with the fluorine-containing gas cylinder 40 or the inert gas cylinder 41 accommodating the laser gas.

Accordingly, the XeF₂ gas generated in the XeF₂ vaporization space 47 can be supplied to the laser chamber 10 together with the laser gas supplied from the gas cylinder having a higher pressure than the laser chamber 10.

According to the first embodiment, the valve V4 is arranged in the pipe connecting the buffer tank 47a and the fluorine-containing gas cylinder 40 or the inert gas cylinder 41. After the pressure in the XeF₂ vaporization space 47 reaches the target vapor pressure VPt, the processor 130 closes the valve V2 and opens the valves V1, V4, thereby supplying the gas in the buffer tank 47a to the laser chamber 10 together with the laser gas supplied from the fluorine-containing gas cylinder 40 or the inert gas cylinder 41.

Accordingly, by supplying the laser gas from the gas cylinder to the buffer tank 47a, the XeF₂ gas in the buffer tank 47a is supplied to the laser chamber 10 without waste, so that the amount of the XeF₂ gas supplied to the laser chamber 10 can be adjusted with high accuracy.

According to the first embodiment, the valve V5 is arranged in the pipe connecting the XeF₂ container 47b and the fluorine-containing gas cylinder 40 or the inert gas cylinder 41.

Accordingly, the inside of the XeF₂ container 47b is filled with a gas during the period in which the XeF₂ crystal 54 is not used (S504 to S506), so that vaporization of the XeF₂ crystal 54 can be suppressed.

According to the first embodiment, the XeF₂ container 47b is filled with the inert gas supplied via the valve V5.

Accordingly, the inside of the XeF₂ container 47b is filled with the inert gas during the period in which the XeF₂ crystal 54 is not used (S504 to S506), so that reaction of the gas can be suppressed.

In other respects, the first embodiment is similar to the comparative example.

### 3. Dissociation of XeF₂ Gas by Discharge Reactor

### 3.1 Configuration

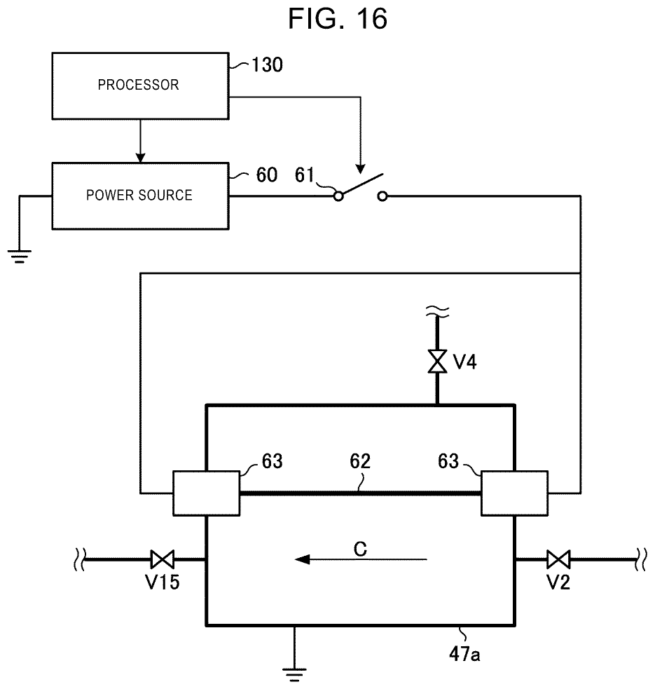

FIG. 16 shows the configuration of the buffer tank 47a in a second embodiment. The buffer tank 47a includes an electrode 62 connected to a power source 60 via feedthroughs 63. The power source 60 is preferably an AC power source or a pulse power source. A switch 61 is arranged between the power source 60 and the feedthroughs 63. The power source 60 and the switch 61 are controlled by the processor 130. Conductive material forming the buffer tank 47a is connected to the ground potential. The electrode 62 corresponds to a discharge reactor in the present disclosure.

The XeF₂ gas flows into the buffer tank 47a via the valve V2. The gas in the buffer tank 47a is supplied to the laser chamber 10 via the valve V15. Thus, a gas flow may be generated in the buffer tank 47a as indicated by arrow C in FIG. 16. The longitudinal direction of the electrode 62 may substantially coincide with the direction of the gas flow.

In order to efficiently dissociate the XeF₂ gas, a plurality of the buffer tanks 47a may be arranged in one laser device 100, and a discharge reactor may be provided in each of the buffer tanks.

In other respects, the configuration of the second embodiment is similar to that of the first embodiment.

### 3.2 Operation

FIG. 17 is a flowchart showing details of processing of generating the XeF₂ gas in the XeF₂ container 47b in the second embodiment. The processes shown in FIG. 17 correspond to the subroutine of S200 of FIG. 7. In the second embodiment, the XeF₂ gas generated in the XeF₂ container 47b is dissociated by the discharge reactor in the buffer tank 47a.

Processes of S201 to S206 are similar to those described with reference to FIG. 9, and communication between the XeF₂ container 47b and the buffer tank 47a is blocked in a state in which each of the XeF₂ container 47b and the buffer tank 47a is filled with the XeF₂ gas of the target vapor pressure VPt.

In S207, the processor 130 turns on the switch 61. Accordingly, discharge occurs between the electrode 62 and the conductive material of the grounded buffer tank 47a, and dissociation of the XeF₂ gas is started.

In S208, the processor 130 waits until a predetermined period of time Tw elapses. In S209, the processor 130 turns off the switch 61.

After S209, the processor 130 terminates processing of the present flowchart and returns to processing shown in FIG. 7.

### 3.3 Effect

According to the second embodiment, the buffer tank 47a includes the electrode 62 as the discharge reactor for dissociating the XeF₂ gas.

Accordingly, since the XeF₂ gas can be supplied to the laser chamber 10 while being dissociated into a xenon gas and a fluorine gas, stable pulse energy E can be obtained from the first discharge after the gas supply.

In other respects, the second embodiment is similar to the first embodiment.

### 4. Gas Regeneration Device Including Buffer Tank 47a

### 4.1 Configuration

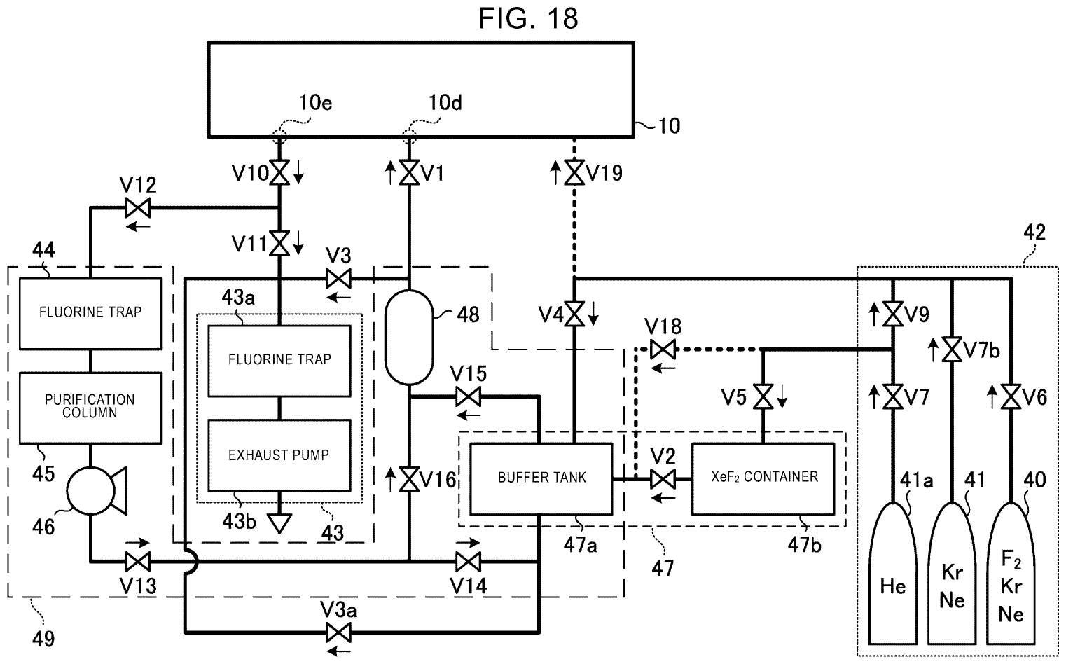

FIG. 18 shows a mechanism for supplying the xenon gas in a third embodiment. The mechanism includes a gas regeneration device 49. The pipe including the valve V10 branches into a pipe including a valve V11 and a pipe including a valve V12. The gas having passed through the valve V11 flows to the exhaust device 43, and the gas having passed through the valve V12 flows to the gas regeneration device 49.

The gas regeneration device 49 includes a fluorine trap 44, a purification column 45, a booster pump 46, and a regeneration gas tank 48. The fluorine trap 44 removes at least fluorine from the laser gas. The purification column 45 includes a filter for removing impurities. The laser gas having passed through the purification column 45 is also referred to as a regeneration gas. The booster pump 46 feeds the regeneration gas at a pressure higher than the inside of the laser chamber 10.

The regeneration gas fed from the booster pump 46 and having passed through a valve V13 passes through either a first path routed through a valve V14, the buffer tank 47a, and the valve V15 in this order, or a second path branching from the first path, from upstream of the valve V14 in the first path, and merging into the into first path, downstream of the valve V15 in the first path, as bypassing the buffer tank 47a. A valve V16 is arranged in the second path.

The regeneration gas tank 48 is arranged between the valve V15 and the valve V1. In the third embodiment, the valve V3 is used when the regeneration gas tank 48 is to be exhausted. When the buffer tank 47a is exhausted, a pipe including a valve V3a is used instead of the pipe including the valve V3.

A pipe including a valve V7b is connected to the inert gas cylinder 41 instead of the pipe including the valves V7, V9. The inert gas accommodated in the inert gas cylinder 41 is supplied to the buffer tank 47a as passing through the valve V4. A helium gas cylinder 41a is connected to the pipe including the valve V7 instead of the inert gas cylinder 41. The helium gas accommodated in the helium gas cylinder 41a is supplied to the XeF₂ container 47b as passing through the valve V5. As described above, the inert gas filled in the XeF₂ container 47b may be the helium gas, and may be a gas different from the gas contained in the laser gas supplied to the laser chamber 10. The configuration for filling the XeF₂ container 47b with the helium gas can also be adopted in the first and second embodiments.

In other respects, the third embodiment is similar to the first embodiment. Alternatively, in the third embodiment, the buffer tank 47a including the discharge reactor may be arranged as in the second embodiment.

### 4.2 Operation of Xenon Addition in Gas Regeneration Device 49

When the laser chamber 10 is filled with the laser gas, the regeneration gas regenerated in the gas regeneration device 49 may be used instead of a new gas supplied from the gas supply device 42, thereby saving resources. However, since the gas regeneration device 49 includes the fluorine trap 44 and the regeneration gas contains almost no fluorine gas, the fluorine concentration in the laser chamber 10 decreases only by supplying the regeneration gas to the laser chamber 10 as it is. Therefore, a fluorine-containing gas is added when the regeneration gas is supplied to the laser chamber 10.

Since the fluorine-containing gas does not contain the xenon gas, the xenon concentration Cx in the laser chamber 10 decreases when the supply of the regeneration gas and the addition of the fluorine-containing gas are repeated. Therefore, by adding the xenon gas in accordance with the addition amount of the fluorine-containing gas, a decrease in the xenon concentration Cx can be suppressed. The method for adjusting the addition amount of the xenon gas is similar to that in the first embodiment.

### 4.3 Operation of Xenon Addition in New Gas Supply

Operation of the xenon addition when a new gas is supplied from the gas supply device 42 to the laser chamber 10 is similar to that described with reference to FIGS. 7 to 13 and FIG. 17. However, the following points are changed.
(1) Instead of opening and closing the valves V3, V15 together in S201 and S203 of FIGS. 9 and 17, or in S501 and S503 of FIG. 12, the valve V3a is opened and closed in the third embodiment.
(2) Instead of opening and closing the valve V10 in S301 and S304 of FIG. 10, the valves V10, V11 are opened and closed together in the third embodiment.
(3) Instead of opening and closing the valves V7, V9 together in S405 and S408 of FIG. 11, the valve V7b is opened and closed in the third embodiment.

### 4.4 Effect

According to the third embodiment, the inert gas filled in the XeF₂ container 47b is a gas different from the gas contained in the laser gas supplied to the laser chamber 10.

Since the inert gas filled in the XeF₂ container 47b is to be exhausted (S201 to S203), the inert gas does not need to be the same as the gas contained in the laser gas, and a cheaper gas can be used.

According to the third embodiment, the laser device 100 further includes the gas regeneration device 49 that purifies and boosts the laser gas discharged from the laser chamber 10, and the buffer tank 47a is arranged in a path for the gas regeneration device 49.

Accordingly, when the fluorine-containing gas is supplied to the laser chamber 10 together with the regeneration gas having the fluorine gas concentration reduced in the gas regeneration device 49, it is possible to compensate for the reduction in the xenon concentration Cx.

According to the third embodiment, the gas regeneration device 49 includes the first path routed through the buffer tank 47a, and the second path branching from the first path, from upstream of the buffer tank 47a in the first path, and merging into the first path, into downstream of the buffer tank 47a in the first path, as bypassing the buffer tank 47a.

Accordingly, when addition of the XeF₂ gas to the regeneration gas is not required, the regeneration gas can be supplied to the laser chamber 10 without passing through the buffer tank 47a.

In other respects, the third embodiment is similar to the first or second embodiment.

### 5. XeF₂ Crystal 54 Arranged in Flow Path of Gas Flow Generated by Cross Flow Fan 21

### 5.1 Configuration

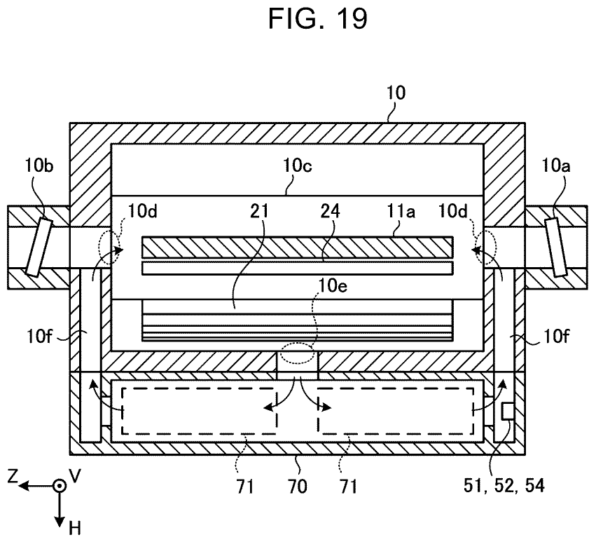

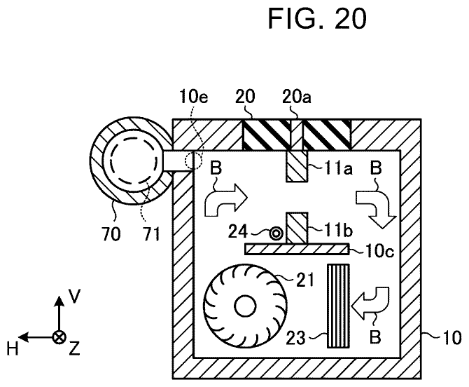

FIG. 19 shows the configuration of a part of the laser device 100 according to a fourth embodiment viewed in the −V direction. FIG. 20 shows the configuration of a part of the laser device 100 according to the fourth embodiment viewed in the Z direction.

In the fourth embodiment, a filter case 70 is connected to the laser chamber r 10. The filter case 70 accommodates a filter 71. The filter case 70 communicates with the inside of the laser chamber 10 via a gas discharge port 10e provided in the wall of the laser chamber 10 at substantially the center in the longitudinal direction of the discharge electrode 11a and an in-wall gas path 10f provided in the wall of the laser chamber 10 at both ends in the longitudinal direction of the discharge electrode 11a. The in-wall gas path 10f is opened to the inside of the laser chamber 10 at the gas supply port 10d located in the vicinity of the windows 10a, 10b.

Utilizing the gas flow generated by the cross flow fan 21, the laser gas flows through the gas flow path from the gas discharge port 10e to the gas supply port 10d via the filter case 70 and the in-wall gas path 10f. The XeF₂ crystal 54 is arranged in the gas flow path. The gas flow path is an example of the XeF₂ vaporization space in the present disclosure. The XeF₂ crystal 54 is preferably arranged downstream of the filter 71 in the gas flow path.

Alternatively, the XeF₂ crystal 54 may be located at an arbitrary position in the laser chamber 10. In this case, the XeF₂ vaporization space in the present disclosure may not be a container different from the laser chamber 10, and the space in the laser chamber 10 also corresponds to the XeF₂ vaporization space in the present disclosure.

The temperature sensor 51 and the temperature adjuster 52 are arranged on a wall surface of the gas flow path and in the vicinity of the XeF₂ crystal 54. The processor 130 (see FIG. 2) controls the temperature adjuster 52 based on the temperature T of the XeF₂ crystal 54 measured by the temperature sensor 51.

The gas supply device 42 and the exhaust device 43 shown in FIG. 2 are also connected to the laser chamber 10. Here, the gas supply device 42 may not include the xenon gas cylinder 41c.

### 5.2 Operation

There are the following two methods for adjusting the xenon concentration Cx in the laser chamber 10 into the optimum range.

In a first method, first, the inside of the laser chamber 10 is exhausted to a substantially vacuum state by the exhaust device 43, and then all valves connected to the outside of the laser chamber 10 are closed. Then, the XeF₂ gas is generated from the XeF₂ crystal 54. When the pressure in the laser chamber 10 has reached the vapor pressure VP of the XeF₂ crystal 54, the laser gas having the target total pressure Pt is introduced into the laser chamber 10 by the gas supply device 42. When the XeF₂ concentration VP/Pt in the laser chamber 10 at this time is X times the optimum value, the laser gas in the laser chamber 10 is further exhausted until the pressure therein becomes Pt/X. Thus, the amount of the XeF₂ gas in the laser chamber 10 is adjusted. When the first method is used, the temperature sensor 51 and the temperature adjuster 52 may be omitted.

In a second method, first, the inside of the laser chamber 10 is exhausted to a substantially vacuum state by the exhaust device 43, and then the laser gas is supplied to the laser chamber 10 by the gas supply device 42 so that the pressure in the laser chamber 10 becomes a first set pressure Pi. Next, the temperature adjuster 52 is controlled so that the vapor pressure VP of the XeF₂ crystal 54 becomes a second set pressure Pj higher than the first set pressure Pi, and an XeF₂ gas partial pressure after waiting for a sufficient time of period becomes Pj−Pi. The first and second set pressures Pi, Pj are set so as to obtain a desired XeF₂ gas partial pressure, whereby the amount of the XeF₂ gas in the laser chamber 10 is adjusted.

### 5.3 Effect

According to the fourth embodiment, the laser device 100 further includes the cross flow fan 21, the gas discharge port 10e arranged in the laser chamber 10, and the gas flow path. The cross flow fan 21 is arranged in the laser chamber 10, and causes the laser gas in the laser chamber 10 to circulate through the laser chamber 10. The gas flow path utilizes the gas flow generated by the cross flow fan 21 so that the laser gas discharged from the laser chamber 10 through the gas discharge port 10e returns to the laser chamber 10 through the gas supply port 10d. The XeF₂ crystal 54 is arranged in the gas flow path.

Accordingly, equipment for supplying the XeF₂ gas generated from the XeF₂ crystal 54 to the laser chamber 10 can be simplified.

According to the fourth embodiment, the laser device 100 further includes the filter 71 arranged in the gas flow path. The XeF₂ crystal 54 is arranged downstream of the filter 71 in the gas flow path.

Accordingly, by arranging the XeF₂ crystal 54 downstream of the filter 71, it is possible to suppress difficulty of generating the XeF₂ gas due to impurities or dust adhering to the surface of the XeF₂ crystal 54.

According to the fourth embodiment, the laser device 100 includes the exhaust device 43 for exhausting the inside of the laser chamber 10, the gas supply device 42 for supplying the laser gas to the laser chamber 10, and the processor 130. The processor 130 controls the exhaust device 43 to exhaust the laser chamber 10, controls the gas supply device 42 to supply the laser gas to the laser chamber 10 when the pressure in the laser chamber 10 has reached the vapor pressure VP of the XeF₂ crystal 54, and controls the exhaust device 43 to exhaust a part of the laser gas from the laser chamber 10, thereby adjusting the amount of the XeF₂ gas in the laser chamber 10.

Accordingly, even when a large amount of the XeF₂ gas is generated, the amount of the XeF₂ gas in the laser chamber 10 can be adjusted by exhausting a part of the laser gas.

According to the fourth embodiment, the laser device 100 includes the temperature adjuster 52 for adjusting the temperature T of the XeF₂ crystal 54, the gas supply device 42 for supplying the laser gas to the laser chamber 10, and the processor 130. The processor 130 controls the gas supply device 42 so that the laser gas is supplied to the laser chamber 10 until the pressure in the laser chamber 10 becomes the first set pressure Pi, and controls the temperature adjuster 52 such that the vapor pressure VP of the XeF₂ crystal 54 becomes the second set pressure Pj higher than the first set pressure Pi, thereby adjusting the amount of the XeF₂ gas in the laser chamber 10.

Accordingly, since the generation amount of the XeF₂ gas corresponds to the difference between the first and second set pressures Pi, Pj, the generation amount of the XeF₂ gas can be adjusted.

In other respects, the fourth embodiment is similar to the first embodiment.

### 6. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements.

Further, indefinite articles “a/an” described in the specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser device comprising:
a laser chamber configured to accommodate laser gas including fluorine;
a pair of discharge electrodes arranged inside the laser chamber;
a gas supply port arranged in the laser chamber; and
an XeF₂ crystal to be vaporized as being arranged in an XeF₂ vaporization space communicating with the gas supply port.

2. The laser device according to claim 1, further comprising:
a temperature adjuster configured to adjust a temperature of the XeF₂ crystal.

3. The laser device according to claim 2, further comprising:
a processor for controlling the temperature adjuster based on a target total pressure and target xenon concentration of the laser gas in the laser chamber.

4. The laser device according to claim 3,
wherein the processor determines a target vapor pressure of the XeF₂ crystal based on the target total pressure and the target xenon concentration, and controls the temperature adjuster based on the target vapor pressure.

5. The laser device according to claim 2,
wherein the XeF₂ vaporization space communicates with the laser chamber via a first pipe including a first valve.

6. The laser device according to claim 5,
wherein the XeF₂ vaporization space includes a buffer tank communicating with the laser chamber via the first pipe, and an XeF₂ container communicating with the buffer tank via a second pipe including a second valve and accommodating the XeF₂ crystal.

7. The laser device according to claim 6, further comprising:
an exhaust device for exhausting an inside of the XeF₂ vaporization space, a third valve arranged between the XeF₂ vaporization space and the exhaust device, and a processor,
wherein the processor opens the third valve and controls the exhaust device so that a pressure in the XeF₂ vaporization space becomes a first pressure, and closes the third valve and controls the temperature adjuster so that the vapor pressure of the XeF₂ crystal becomes a second pressure higher than the first pressure.

8. The laser device according to claim 7,
wherein the XeF₂ vaporization space communicates with a gas cylinder accommodating a laser gas.

9. The laser device according to claim 8,
wherein a fourth valve is arranged in a pipe connecting the buffer tank and the gas cylinder, and
the processor supplies a gas in the buffer tank to the laser chamber together with the laser gas supplied from the gas cylinder by closing the second valve after the pressure in the XeF₂ vaporization space reaches the second pressure and opening the fourth valve and the first valve.

10. The laser device according to claim 8,
wherein a fifth valve is arranged in a pipe connecting the XeF₂ container and the gas cylinder.

11. The laser device according to claim 10,
wherein the XeF₂ container is filled with an inert gas supplied via the fifth valve.

12. The laser device according to claim 11,
wherein the inert gas filled in the XeF₂ container is a gas different from a gas contained in the laser gas supplied to the laser chamber.

13. The laser device according to claim 6,
wherein the buffer tank includes a discharge reactor for dissociating an XeF₂ gas.

14. The laser device according to claim 6, further comprising:
a gas regeneration device that purifies and boosts the laser gas discharged from the laser chamber,
wherein the buffer tank is arranged in a path for the gas regeneration device.

15. The laser device according to claim 14,
Wherein the gas regeneration device includes a first path routed through the buffer tank, and a second path branching from the first path, from upstream of the buffer tank in the first path, and merging into the first path, into downstream of the buffer tank in the first path, as bypassing the buffer tank.

16. The laser device according to claim 1, further comprising:
a fan arranged in the laser chamber, and configured to cause the laser gas in the laser chamber to circulate through the laser chamber;
a gas discharge port arranged in the laser chamber; and
a gas flow path configured to return the laser gas discharged from the laser chamber through the gas discharge port to the laser chamber through the gas supply port by utilizing a gas flow generated by the fan,
wherein the XeF₂ crystal is arranged in the gas flow path.

17. The laser device according to claim 16, further comprising:
a filter arranged in the gas flow path,
wherein the XeF₂ crystal is arranged downstream of the filter in the gas flow path.

18. The laser device according to claim 16, further comprising:
an exhaust device configured to exhaust the laser chamber;
a gas supply device configured to supply the laser gas into the laser chamber; and
a processor,
wherein the processor controls the exhaust device to exhaust the laser chamber, controls the gas supply device to supply the laser gas into the laser chamber when a pressure in the laser chamber has reached a vapor pressure of the XeF₂ crystal, and controls the exhaust device to exhaust a part of the laser gas from the laser chamber, thereby adjusting an amount of an XeF₂ gas in the laser chamber.

19. The laser device according to claim 16, further comprising:
a temperature adjuster configured to adjust a temperature of the XeF₂ crystal;
a gas supply device configured to supply the laser gas into the laser chamber; and
a processor,
wherein the processor controls the gas supply device so that the laser gas is supplied to the laser chamber until a pressure in the laser chamber becomes a first set pressure, and controls the temperature adjuster so that a vapor pressure of the XeF₂ crystal becomes a second set pressure higher than the first set pressure, thereby adjusting an amount of an XeF₂ gas in the laser chamber.

20. An electronic device manufacturing method, comprising:
generating laser light using a laser device;
outputting the laser light to an exposure apparatus; and
exposing a photosensitive substrate to the laser light in the exposure apparatus to manufacture an electronic device,
the laser device including:
a laser chamber configured to accommodate laser gas including fluorine;
a pair of discharge electrodes arranged inside the laser chamber;
a gas supply port arranged in the laser chamber; and an XeF₂ crystal to be vaporized as being arranged in an XeF₂ vaporization space communicating with the gas supply port.
